(19) United States
(12) Patent Application Publication
(10) Pub. No.: US 2026/0282715 A1
(43) Pub. Date: Sep. 17, 2026

(54) LIGHT EMITTING DISPLAY APPARATUS

(71) Applicant: LG Display Co., Ltd., Seoul (KR)

(72) Inventors: Kyuhwan LEE, Paju-si (KR); InGoo LEE, Paju-si (KR); SeoHyun NAM, Paju-si (KR); YoungNam LIM, Paju-si (KR); HyeSun JUNG, Paju-si (KR); SeHong PARK, Paju-si (KR); Hyeonhye YU, Paju-si (KR)

(21) Appl. No.: 19/458,882

(22) Filed: Jan. 25, 2026

(30) Foreign Application Priority Data
Mar. 14, 2025 (KR) 10-2025-0033573
Jun. 30, 2025 (KR) 10-2025-0087423
Dec. 9, 2025 (KR) 10-2025-0193653

(51) Int. Cl. H10K 59/80

(52) U.S. Cl. CPC H10K 59/877

(57) ABSTRACT

A light emitting display apparatus includes a substrate including a plurality of subpixels each including an emission area and a non-emission area, an overcoat layer on the emission area and the non-emission area, a light emitting device layer on the overcoat layer and including a first electrode including a surface modification layer, an emission part on the first electrode, and a second electrode on the emission part, and a scattering layer between the first electrode and the emission part and contacting the surface modification layer. The emission part includes an emission layer, a hole functional layer between the scattering layer and the emission layer, and an electron functional layer between the emission layer and the second electrode, and the scattering layer includes an intermolecular stack structure forming a light scattering surface.

### CROSS REFERENCE TO RELATED APPLICATIONS

This application claims priority from and the benefit of Korean Patent Application Nos. 10-2025-0033573, filed on Mar. 14, 2025, 10-2025-0087423, filed on Jun. 30, 2025, and 10-2025-0193653, filed on Dec. 9, 2025, which are hereby incorporated by reference for all purposes as if fully set forth herein.

### BACKGROUND

### Field

Embodiments of the invention relate generally to a light emitting display apparatus.

### Discussion of the Background

Light emitting display apparatuses are being widely used as display screens in various products such as portable electronic devices such as smartphones and personal computers (PCs), wearable devices such as smartwatches, televisions (TVs), notebook computers, and monitors. For example, display apparatuses may include a display panel including a plurality of pixels which display an image, based on light emitted by a light emitting device.

Light emitting display apparatuses may display an image through light emitted by an emission part disposed between two electrodes, for example, an anode electrode and a cathode electrode.

In light emitting display apparatuses, light emitting devices may have a structure and a thickness based on a micro-cavity distance between two electrodes according to a wavelength of light emitted from an emission part, in order to enhance the light extraction efficiency.

However, an intensity of light emitted from each light emitting device may be increased due to a micro-cavity distance, and as a result, a viewing angle characteristic of the light emitting display apparatus may be degraded. For example, based on a micro-cavity structure, light emitted from each of a plurality of light emitting devices may concentrate on the front of the display apparatus, and as a result, there may be a problem where a luminance viewing angle of light is narrow, resulting in decreased light extraction.

The above information disclosed in this Background section is only for understanding of the background of the inventive concepts, and, therefore, it may contain information that does not constitute prior art.

### SUMMARY

Accordingly, research and experiments regarding a light emitting display apparatus having an enhanced luminance viewing angle characteristic has been continuously performed. Based on the research and experiments, a light emitting display apparatus having an enhanced luminance viewing angle characteristic is disclosed according to embodiment of the invention.

Embodiments of the invention relate to a light emitting display apparatus having an enhanced luminance viewing angle characteristic.

Embodiments of the invention relate to providing a light emitting display apparatus where a luminance viewing angle characteristic and the increased light extraction efficiency.

An embodiment of the invention is directed to providing a light emitting display apparatus having reduced power consumption through low power driving based on increased light extraction efficiency.

Additional features of the inventive concepts will be set forth in the description which follows, and in part will be apparent from the description, or may be learned by practice of the inventive concepts.

According to an embodiment, a light emitting display apparatus includes a substrate including a plurality of subpixels each including an emission area and a non-emission area, an overcoat layer on the emission area and the non-emission area, a light emitting device layer on the overcoat layer and including a first electrode including a surface modification layer, an emission part on the first electrode, and a second electrode on the emission part, and a scattering layer between the first electrode and the emission part and contacting the surface modification layer, wherein the emission part includes an emission layer, a hole functional layer between the scattering layer and the emission layer, and an electron functional layer between the emission layer and the second electrode, and the scattering layer includes an intermolecular stack structure forming a light scattering surface.

According to another embodiment, a light emitting display apparatus includes a substrate including a plurality of subpixels each including an emission area and a non-emission area, a thin film transistor in the non-emission area, an overcoat layer in the emission area and the non-emission area and covering the thin film transistor, a scattering layer on the overcoat layer, and a light emitting device layer on the scattering layer and including a first electrode connected to the thin film transistor, an emission part on the first electrode, and a second electrode on the emission part, wherein the scattering layer includes an intermolecular stack structure forming a light scattering surface.

According to another embodiment, a light emitting display apparatus includes a substrate including a plurality of subpixels each including an emission area and a non-emission area, an overcoat layer on the emission area and the non-emission area, a light emitting device layer on the overcoat layer and including a first electrode including a surface modification layer, an emission part on the first electrode, and a second electrode on the emission part, and a scattering layer between the first electrode and the emission part and contacting the surface modification layer, wherein the emission part includes an emission layer, a hole functional layer between the scattering layer and the emission layer, and an electron functional layer between the emission layer and the second electrode, and the scattering layer includes a molecular structure comprising an organic material including a plurality of aromatic rings and a double bond structure and at least two of the plurality of aromatic rings are rotatable relative to each other.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a diagram for describing a light emitting display apparatus according to an embodiment of the invention.

FIG. 2 is a plan view schematically illustrating one pixel in a light emitting display apparatus according to an embodiment of the invention.

FIG. 3 is a cross-sectional view illustrating an embodiment taken along line I-I′ of FIG. 2.

FIG. 4 is a cross-sectional view illustrating an embodiment taken along line II-II′ of FIG. 2.

FIG. 5 is an enlarged view of a portion A illustrated in FIG. 3.

FIG. 6 is a diagram illustrating an energy level diagram of a light emitting display apparatus according to an embodiment of the invention.

FIG. 7 is a cross-sectional view illustrating an embodiment taken along line I-I′ of FIG. 2.

FIG. 8 is a cross-sectional view illustrating an embodiment taken along line II-II′ of FIG. 2.

FIG. 9 is an enlarged view of a portion B illustrated in FIG. 7.

FIG. 10 is a diagram illustrating a roughness of a light scattering surface with respect to a thickness of a scattering layer, in a light emitting display apparatus according to an embodiment of the invention.

FIG. 11 is a cross-sectional view illustrating an embodiment taken along line II-II′ of FIG. 2.

FIG. 12 is a graph showing a luminance of one subpixel according to an experimental example and an embodiment of the invention.

### DETAILED DESCRIPTION OF THE DISCLOSURE

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

A light emitting display apparatus according to an embodiment of the invention is a flexible light emitting display apparatus, but is not limited thereto. For example, the light emitting display apparatus according to an embodiment of the invention may include a set electronic or set apparatus, such as a notebook computer, a television (TV), a computer monitor, an equipment apparatus including an automotive display apparatus, a mobile electronic apparatus such as a smartphone and a tablet personal computer (PC), or a wearable apparatus such as a smart watch, which is a complete or a final product including a display panel.

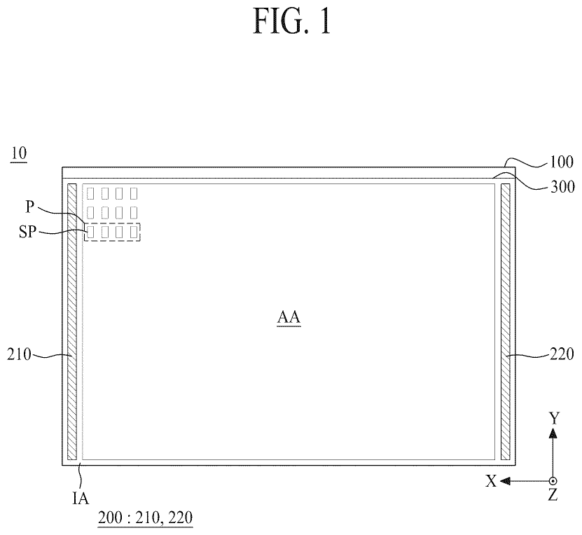

FIG. 1 is a diagram for describing a light emitting display apparatus according to an embodiment of the invention.

Referring to FIG. 1, the light emitting display apparatus according to an embodiment of the invention may include a light emitting display panel or a display panel 10.

The display panel 10 may include a plurality of pixels P disposed on a substrate 100.

The substrate 100 may include a display area AA and a non-display area IA.

The display area AA may be an area which displays an image and may be a pixel array area, an active area, a pixel array part, a display part, or a screen. The display area AA may include the plurality of pixels P.

The plurality of pixels P may be disposed in the display area AA to display an image.

The plurality of pixels P may be arranged in a first direction X (such as a horizontal line) and a second direction Y (such as a vertical line) intersecting with the first direction X. Each of the plurality of pixels P may be a unit pixel (or a unit area) which displays a real image. Each of the plurality of pixels P may include a plurality of adjacent subpixels SP.

At least four adjacent subpixels SP among a plurality of subpixels SP may configure one pixel (or unit pixel) P which implements a color image. For example, the pixel P may include first to fourth subpixels SP which each emit different colored light. For example, the pixel P may be a RWBG stripe type pixel, and the first subpixel SP may be a red subpixel which emits red light, the second subpixel SP may be a white subpixel which emits white light, the third subpixel SP may be a blue subpixel which emits blue light, and the fourth subpixel SP may be a green subpixel that emits green light, but embodiments of the invention are not limited thereto.

Each of the plurality of subpixels SP may be connected to a pixel driving line and may be configured to emit light based on a signal supplied through the pixel driving line. Each of the plurality of subpixels SP may be configured to be electrically connected to the pixel driving line which includes a gate line, a data line, and a pixel driving power line. Each of the plurality of subpixels SP may include a light emitting device for displaying an image and a pixel circuit including a plurality of thin film transistors connected to the pixel driving line to independently drive the light emitting device.

The plurality of subpixels SP according to an embodiment may be arranged to have a planar structure of an RWBG stripe type, but are not limited thereto. According to another embodiment, the plurality of subpixels SP may be arranged to have a planar structure of a pentile type.

The non-display area IA may be an area which does not display an image and may be a peripheral circuit area, a signal supply area, an inactive area, or a bezel area. The non-display area IA may be configured to surround the display area AA.

The display panel 10 or the substrate 100 may further include a peripheral circuit unit 200 disposed in the non-display area IA. The peripheral circuit unit 200 may include gate driving circuits 210 and 220 connected to a plurality of subpixels SP.

The gate driving circuits 210 and 220 may be disposed in the non-display area IA of the substrate 100 and may be configured to drive a plurality of gate lines disposed in the display area AA. The gate driving circuit may be configured to drive the plurality of gate lines in response to a gate driving control signal including a gate driving voltage supplied through a gate driving voltage line and a plurality of clock signals supplied through a plurality of clock signal lines.

The gate driving circuits 210 and 220 may be directly formed or implemented on the substrate 100 by a manufacturing process of a thin film transistor of each pixel, based on a gate in panel (GIP) type. For example, the gate driving circuits 210 and 220 may be an embedded gate circuit or a gate shift register circuit, but are not limited thereto.

The gate driving circuits 210 and 220 may include one or more of a first gate driving circuit 210 and a second gate driving circuit 220.

The first gate driving circuit 210 may be implemented in the non-display area IA adjacent to a first side of the display area AA. The second gate driving circuit 220 may be implemented in the non-display area IA adjacent to a second side opposite to the first side of the display area AA. The gate driving circuits 210 and 220 may be configured to supply a first scan signal, a second scan signal, a first emission control signal, and a second emission control signal to the plurality of subpixels SP, but are not limited thereto. For example, the signals supplied from the gate driving circuits 210 and 220 to the subpixels SP may be based on a configuration of the pixel circuit.

The light emitting display device or the display panel 10 according to an embodiment of the invention may further include a cover window 300.

The cover window 300 may be configured to protect the display panel 10. The cover window 300 may have a larger size than that of the substrate 100 and may include a transparent material. For example, the cover window 300 may include a plastic material or a glass material.

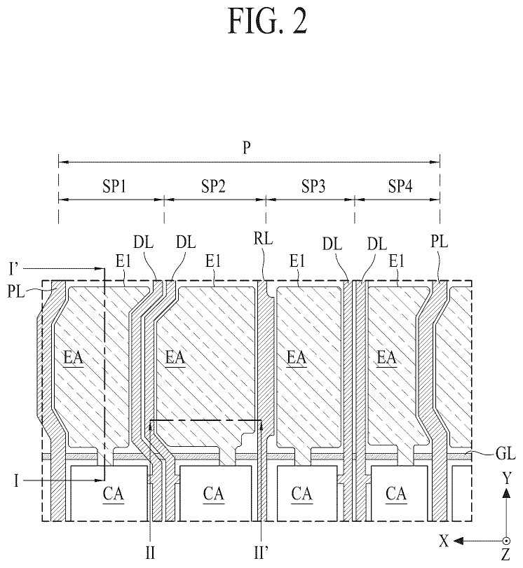

FIG. 2 is a plan view schematically illustrating one pixel in a light emitting display apparatus according to an embodiment of the invention.

Referring to FIG. 2, in the light emitting display apparatus according to an embodiment of the invention, each of the plurality of pixels P may include four subpixels SP1 to SP4. For example, each of the plurality of pixels P may include a red first subpixel SP1, a white second subpixel SP2, a blue third subpixel SP3, and a green fourth subpixel SP4.

Each of the first to fourth subpixels SP1 to SP4 may include an emission area EA and a circuit area CA. The emission area EA may be disposed on one side of the subpixel area, and the circuit area CA may be disposed on a second side of the subpixel area. For example, the circuit area CA may be disposed under the emission area EA with respect to the second direction Y. The emission area EA of each of the first to fourth subpixels SP1 to SP4 may have different sizes. Each of the first to fourth subpixels SP1 to SP4 may further include a non-emission area surrounding the emission area EA. The non-emission area may include the circuit area CA.

The first to fourth subpixels SP1 to SP4 may each be arranged adjacent to each other in the first direction X. For example, two data lines DL extending in the second direction Y may be arranged in parallel between the first subpixel SP1 and the second subpixel SP2 and between the third subpixel SP3 and the fourth subpixel SP4. A gate line GL extending in the first direction X may be disposed between the emission area EA and the circuit area CA of each of the first to fourth subpixels SP1 to SP4.

A pixel power line PL extending in the second direction Y may be disposed at one side of the first subpixel SP1 and the fourth subpixel SP4. A reference line RL extending in the second direction Y may be disposed between the second subpixel SP2 and the third subpixel SP3. The reference line RL may be used as a sensing line for externally sensing a characteristic change of a driving thin film transistor and/or a characteristic change of a light emitting device layer disposed in the circuit area CA in a sensing driving mode of the pixel P.

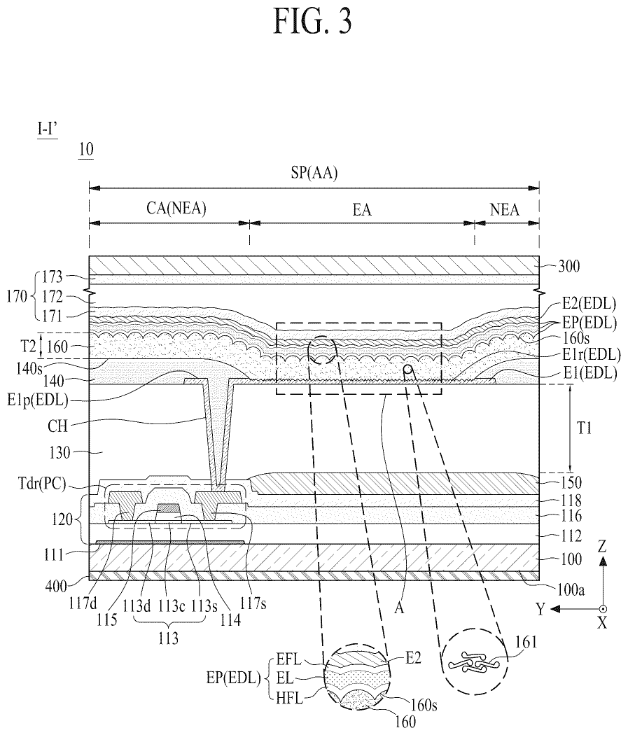

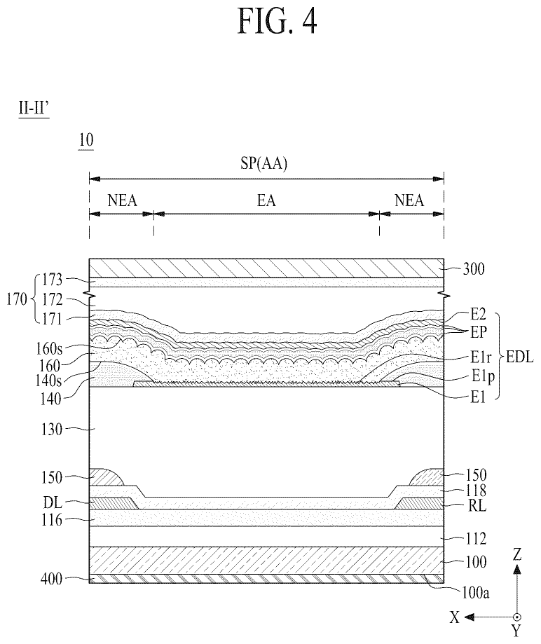

FIG. 3 is a cross-sectional view taken along line I-I′ of FIG. 2 according to an embodiment. FIG. 4 is a cross-sectional view taken along line II-II′ of FIG. 2 according to an embodiment.

Referring to FIG. 3 and FIG. 4, the light emitting display apparatus (or display panel 10 or subpixel SP) according to an embodiment of the invention may include the substrate 100, a pixel circuit unit 120, an overcoat layer 130, a light emitting device layer EDL, and a scattering layer 160.

The substrate 100 may include the plurality of subpixels SP including an emission area EA and a non-emission area NEA. The emission area EA may be an area which emits light using a light emitting device layer EDL. The non-emission area NEA may be a peripheral area of the emission area EA. The non-emission area NEA may be arranged around the emission area EA. The non-emission area NEA may include a circuit area CA where a pixel circuit PC is disposed.

The substrate 100 may include a plastic material or a glass material. For example, the substrate 100 may include one or more plastic material layers, but is not limited thereto.

The pixel circuit unit 120 may include a light blocking electrode 111, a buffer layer 112, and the pixel circuit PC, which are disposed on the substrate 100 of the display area AA.

The light blocking electrode 111 may be disposed on the substrate 100, and may be disposed in the pixel circuit PC. The light blocking electrode 111 may be configured to prevent a threshold voltage Vth of the thin film transistor included in the pixel circuit PC from being shifted by external light incident from the outside of the display panel 10. The light blocking electrode 111 may be electrically connected to a source electrode of a transistor or to a separate bias power source, and may thereby also function as a bottom gate electrode of a corresponding transistor. In such a configuration, light-induced variations in transistor characteristics, including threshold voltage shifts resulting from an applied bias voltage may be minimized or prevented.

The buffer layer 112 may cover the light blocking electrode 111 and may be disposed on the substrate 100. The buffer layer 112 may prevent materials included in the substrate 100 from diffusing into the transistor during high-temperature manufacturing processes of the thin-film transistor. The buffer layer 112 may also prevent external water or moisture from permeating into the pixel circuit PC and/or the light emitting device layer EDL. For example, the buffer layer 112 may include an inorganic insulating material.

The pixel circuit PC may include a driving thin film transistor Tdr disposed in a pixel area of the circuit area CA on the buffer layer 112.

The driving thin film transistor Tdr may include a semiconductor layer 113, a gate electrode 115, a source electrode 117s, and a drain electrode 117d.

The semiconductor layer 113 may be disposed on the buffer layer 112. For example, the semiconductor layer 113 may include a metal oxide semiconductor material such as indium-gallium-zinc-oxide (IGZO), but is not limited thereto, and may include a silicon-based semiconductor material such as amorphous silicon or polycrystalline silicon.

The semiconductor layer 113 may include a source region 113s, a drain region 113d, and a channel region 113c between the source region 113s and the drain region 113d. At least a portion of the semiconductor layer 113 may be covered by a gate insulation layer 114.

The gate insulation layer 114 may be formed in an island shape on only the channel region 113c of the semiconductor layer 113, or may be formed to cover an entire surface of the buffer layer 112 or the substrate 100 including the semiconductor layer 113. The gate insulation layer 114 may include an inorganic material, but is not limited thereto, and may also include an organic material.

The gate electrode 115 may be disposed on the gate insulation layer 114 to overlap the channel region 113c of the semiconductor layer 113. The gate electrode 115 may be formed of a gate metal material. The gate electrode 115 may be formed together with the gate line. The gate electrode 115 may be covered by an interlayer insulation layer 116.

The interlayer insulation layer 116 may be formed on the gate insulation layer 114 to cover the gate electrode 115. The interlayer insulation layer 116 may include an inorganic material, but is not limited thereto, and may also include an organic material.

The source electrode 117s may be disposed on the interlayer insulation layer 116 so as to be electrically connected to the source region 113s of the semiconductor layer 113. The source electrode 117s may be electrically connected to the source region 113s of the semiconductor layer 113 through a contact hole formed in the interlayer insulation layer 116 overlapping the source region 113s of the semiconductor layer 113.

The drain electrode 117d may be disposed on the interlayer insulation layer 116 so as to be electrically connected to the drain region 113d of the semiconductor layer 113. The drain electrode 117d may be electrically connected to the drain region 113d of the semiconductor layer 113 through a contact hole formed in the interlayer insulation layer 116 overlapping the drain region 113d of the semiconductor layer 113.

The pixel circuit PC may further include at least one switching thin film transistor and at least one capacitor. The switching thin film transistor and the capacitor may be formed together with the driving thin film transistor Tdr.

A passivation layer 118 may be disposed on the substrate 100 to cover the pixel circuit PC. For example, the passivation layer 118 may include an inorganic insulating material.

The overcoat layer 130 may be disposed in the emission area EA and the non-emission area NEA on the substrate 100. The overcoat layer 130 may be disposed on the passivation layer 118. The overcoat layer 130 may cover the pixel circuit unit 120. The overcoat layer 130 may include an organic material. The overcoat layer 130 may provide a flat surface on the pixel circuit unit 120. For example, the overcoat layer 130 may have a thickness T1 of several micrometers (μm). For example, the overcoat layer 130 may be formed to have the thickness T1 of 1 μm to 3 μm, but is not limited thereto. For example, the overcoat layer 130 may include one of acrylic resin, epoxy resin, phenolic resin, polyamide resin, and polyimide resin.

Referring to FIG. 2, FIG. 3, and FIG. 4, the display panel 10 according to an embodiment of the invention may further include a color filter layer 150.

The color filter layer 150 may be disposed between the passivation layer 118 and the overcoat layer 130. The color filter layer 150 may be disposed in each of the first subpixel SP1, the third subpixel SP3, and the fourth subpixel SP4 among the plurality of subpixels SP1 to SP4. A red color filter may be disposed in the first subpixel SP1, a blue color filter may be disposed in the third subpixel SP3, and a green color filter may be disposed in the fourth subpixel SP4. The second subpixel SP2 may be a white subpixel and may not include a color filter.

According to an embodiment of the invention, light emitted from the light emitting device layer EDL may pass through the color filter layer 150 and may travel in a downward direction. The display panel 10 according to an embodiment of the invention may be an emission display panel of a bottom emission type.

Referring to FIG. 3 and FIG. 4, the light emitting device layer EDL may be disposed on the overcoat layer 130. The light emitting device layer EDL may be disposed on the overcoat layer 130 of the display area AA.

The light emitting device layer EDL may include a first electrode E1 disposed on the overcoat layer 130, an emission part EP, and a second electrode E2.

The first electrode E1 may be disposed on the overcoat layer 130. The first electrode E1 may be electrically connected to the source electrode 117s of the driving thin film transistor Tdr through a contact hole CH passing through the overcoat layer 130. For example, the first electrode E1 may be individually formed in each of the plurality of pixels. The first electrode E1 may be an anode electrode of the light emitting device layer EDL.

According to an embodiment of the invention, the first electrode E1 may include a transparent conductive oxide. For example, the first electrode E1 may include indium tin oxide (ITO), indium zinc oxide (IZO), or indium gallium zinc oxide (IGZO), but is not limited thereto.

According to an embodiment of the invention, the first electrode E1 may include a surface modification layer E1r formed by a surface treatment, such as an oxygen plasma process.

The surface modification layer E1r may be disposed in the emission area EA of each of the plurality of subpixels SP, such as on an upper surface of the first electrode E1. The surface modification layer E1r may be the upper surface of the first electrode E1 on which surface treatment has been performed by oxygen plasma. The surface modification layer E1r may be disposed between the first electrode E1 and the emission part EP and/or between the first electrode E1 and the scattering layer 160. The surface modification layer E1r may substantially contact the scattering layer 160.

The surface modification layer E1r may be formed on only the upper surface of the first electrode E1 corresponding to the emission area EA of the subpixel SP. For example, the surface modification layer E1r may be formed on only the upper surface of the first electrode E1 in the emission area EA of the subpixel SP and may not be formed on the upper surface of the first electrode E1 corresponding to the non-emission area NEA.

According to an embodiment of the invention, in each of the plurality of subpixels SP, the first electrode E1 may include a first region disposed in the emission area EA, and a second region E1p disposed in the non-emission area NEA. In each of the plurality of subpixels SP, the first region of the first electrode E1 disposed in the emission area EA may have a surface shape which differs from that of the second region E1p of the first electrode E1 disposed in the non-emission area NEA. For example, in the first electrode E1, the second region E1p may include a planar portion or have a surface roughness less than a surface roughness of the first region. For example, in the first electrode E1, the first region may include the surface modification layer E1r, and the second region E1p may include a planar portion extending from the first region to the non-emission area NEA. The planar portion of the second region E1p may include a protrusion portion or a connection portion, which is electrically connected to the source electrode 117s of the driving thin film transistor Tdr through the contact hole CH.

According to an embodiment of the invention, plasma treatment may be performed to increase or optimize a work function of the first electrode E1. The surface modification layer E1r may be configured by performing plasma treatment on the upper surface of the first electrode E1, thereby enhancing a surface roughness, an adhesive force, and hydrophilicity of the first electrode E1.

According to an embodiment of the invention, a plasma treatment performed on the upper surface of the first electrode E1 may cause a physical or chemical surface modification, thereby improving an interface characteristic and an adhesion characteristic between the first electrode E1 and the scattering layer 160. As the first electrode E1 includes the surface modification layer E1r, an adhesion area of the first electrode E1 may increase, and an adhesive force between the first electrode E1 and the scattering layer 160 may be enhanced.

According to an embodiment of the invention, oxygen (O₂) and argon (Ar) gases may be used in a plasma treatment process. For example, the plasma treatment process may be performed with a pressure of 140 mTorr, based on 250 W. For example, a plasma treatment time may be in a range of 20 seconds, to 60 seconds. A surface roughness of the surface modification layer E1r according to an embodiment of the invention may be in a range of 2 nm to less than 10 nm. For example, the surface roughness of the surface modification layer E1r may be adjusted based on the plasma treatment time, and by setting the plasma treatment time to a range of 20 sec to 60 sec under the conditions described above, the surface roughness of the surface modification layer E1r may be adjusted to 2 nm to less than 10 nm.

According to an embodiment of the invention, in the first electrode E1, the first region including the surface modification layer E1r may have a thickness which is less than a thickness of the second region E1p surrounding the first region. For example, in the first electrode E1, the thickness of the first region may be less than that of the second region E1p with respect to a flat surface of the overcoat layer 130, due to the plasma treatment process.

The emission part EP may be disposed between the first electrode E1 and the second electrode E2. The emission part EP may include an organic light emitting structure where a hole functional layer HFL, one or more emission layers EL, and an electron functional layer EFL are stacked on the first electrode E1. The one or more emission layers EL may be interposed between the hole functional layer HFL and the electron functional layer EFL. The hole functional layer HFL may be disposed between the scattering layer 160 and the emission layer EL. The electron functional layer EFL may be disposed between the emission layer EL and the second electrode E2.

According to an embodiment, the emission part EP may include a tandem structure where two emission layers overlap and may further include a charge generation layer disposed between the two emission layers, but is not limited thereto. For example, the emission part EP may include three or more emission stack structure where three or more emission layers are stacked and may further include two or more charge generation layers disposed between the three or more emission stack structures.

According to an embodiment, the emission part EP may be individually configured in each of the plurality of subpixels SP. For example, the emission part EP may be implemented to generate color light corresponding to a corresponding subpixel SP. For example, the emission part EP of the red subpixel SP may include a red organic emission layer, the emission part EP of the green subpixel SP may include a green organic emission layer, and the emission part EP of the blue subpixel SP may include a blue organic emission layer.

In the emission part EP according to an embodiment, the hole functional layer HFL and the electron functional layer EFL of the organic emission structure may be a common layer. The common layer may be disposed in an entire region of the display area AA and a partial region of the non-display area NEA. For example, the common layer may be identically disposed in the plurality of subpixels SP. For example, the hole functional layer HFL may include one or more of a hole injection layer and a hole transport layer, and the electron functional layer EFL may include one or more of an electron injection layer and an electron transport layer.

The second electrode E2 may be disposed on the emission part EP. The second electrode E2 may be formed of a conductive material having a high light transmittance or a semi-transmissive conductive material. For example, the second electrode E2 may be commonly formed in the plurality of subpixels SP, but is not limited thereto. For example, the second electrode E2 may include a plurality of second electrode patterns which are at least partially separated from each other.

The second electrode E2 may include one or more conductive layer structures having a high reflectance. For example, the second electrode E2 may include a single-layer structure or a multi-layer structure including one material selected from among aluminum (Al), silver (Ag), molybdenum (Mo), gold (Au), magnesium (Mg), calcium (Ca), or barium (Ba), or an alloy of two or more thereof.

The emission part EP may directly contact the other portion, except an end portion, of the first electrode E1. The emission part EP may directly contact a portion of a bank insulation layer 140 covering the end portion of the first electrode E1. The second electrode E2 may be a common electrode which is continuously connected along a surface 140s of the bank insulation layer 140.

The light emitting display apparatus or the display panel 10 according to an embodiment of the invention may include the scattering layer 160. The scattering layer 160 may be disposed inside or outside the light emitting device layer EDL.

According to an embodiment of the invention, the scattering layer 160 may be disposed in the light emitting device layer EDL. The scattering layer 160 may be configured in the light emitting device layer EDL to increase a scattering characteristic of light emitted from the emission part EP. Accordingly, the luminance viewing angle characteristic and amount of light extraction of the plurality of subpixels SP or the display panel 10 may be enhanced.

According to an embodiment of the invention, the scattering layer 160 may be disposed on the first electrode E1 of the light emitting device layer EDL. The scattering layer 160 may be disposed on the surface modification layer E1r of the first electrode E1. The scattering layer 160 may directly contact the surface modification layer E1r of the first electrode E1.

The scattering layer 160 may be disposed in the emission area EA and the non-emission area NEA. The scattering layer 160 may be disposed between the first electrode E1 and the emission part EP. The scattering layer 160 may be disposed between the surface modification layer E1r of the first electrode E1 and the emission part EP. The scattering layer 160 may be disposed between the surface modification layer E1r and the hole functional layer HFL in the emission area EA of each of the plurality of subpixels SP.

The scattering layer 160 may include a light scattering surface 160s formed based on an intermolecular stack structure. The emission part EP may cover the light scattering surface 160s and may have a conformal shape corresponding to a surface shape of the light scattering surface 160s. The hole functional layer HFL substantially contacting the scattering layer 160 may cover the light scattering surface 160s and may have a conformal shape corresponding to the surface shape of the light scattering surface 160s.

According to an embodiment of the invention, a surface roughness of the scattering layer 160 or the light scattering surface 160s may be greater than that of the surface modification layer E1r of the first electrode E1.

The surface roughness of the scattering layer 160, for example, root mean square roughness Rq, according to an embodiment may be tens of nanometers or more. For example, the surface roughness of the scattering layer 160 may be at least 30 nm. Accordingly, desired luminance viewing angle in the display panel 10 may be achieved. The light scattering surface 160s of the scattering layer 160 may have a surface roughness of 30 nm to 71 nm. For example, in order to implement a luminance viewing angle of 70% or more for white light, a luminance viewing angle for green light should be 60% or more, thus the roughness Rq of the light scattering surface 160s of the scattering layer 160 may be 63 nm or more, but is not limited thereto.

According to an embodiment of the invention, the scattering layer 160 may be formed of a material different from that of the overcoat layer 130. The scattering layer 160 may be formed to have a second thickness T2 thinner than the first thickness T1 of the overcoat layer 130. For example, the scattering layer 160 may have a thickness T2 of 500 Å to 1500 Å. For example, when the thickness T2 of the scattering layer 160 is less than 500 Å, a non-deposition phenomenon of the scattering layer 160 may occur, and due to this, a luminance viewing angle characteristic may decrease. For example, when the thickness T2 of the scattering layer 160 is greater than 1500 Å, because the scattering layer 160 is configured in the light emitting device layer EDL, a transfer distance of a hole may increase, and a degradation in a light emitting device may occur.

Referring to FIG. 1 and FIG. 3, the scattering layer 160 may be disposed in an entire region of the display area AA and a portion of the non-display area IA. For example, the scattering layer 160 may extend from the display area AA of the substrate 100 to a partial region of the non-display area IA adjacent to an end of the substrate 100.

Referring to FIG. 3 and FIG. 4, the scattering layer 160 may include a material having unevenness or irregular evenness, based on the intermolecular stack structure. The scattering layer 160 may be formed to include the light scattering surface 160s. The scattering layer 160 may include a material, which may include the light scattering surface 160s, based on the intermolecular stack structure. For example, the scattering layer 160 may include a material having a roughness based on the intermolecular stack structure added during a deposition process. For example, the scattering layer 160 may include the light scattering surface 160s through only a deposition process without an additional separate patterning process. For example, the scattering layer 160 may be formed by a thermal evaporation process, but is not limited thereto.

According to an embodiment, the intermolecular stack structure may include a molecular structure 161 comprising a material suitable for forming the scattering layer 160 having the light scattering surface 160s. The molecular structure 161 may include an organic material including a plurality of aromatic rings and a double bond structure, and two or more of the aromatic rings are rotatable relative to each other.

According to an embodiment, a molecular weight of the molecular structure 161 may be 500 or less, and may have a diameter in a range of 10 Å to 25 Å. For example, the number of aromatic rings in the molecular structure 161 may be four or five, and the number of double bond structures may be one. For example, when the molecular structure 161 has a diameter of 10 Å to 25 Å, the number of aromatic rings may be four or five.

According to an embodiment, as the number of rotatable aromatic rings among a plurality of aromatic rings increases in the molecular structure 161, the degree of freedom of the molecule structure 161 may increase, and thus, a roughness of the light scattering surface 160s may increase. For example, a molecule structure 161 of the scattering layer 160 may form the light scattering surface 160s having a roughness structure through self-crystallization based on an asymmetric interaction when stacking molecules during a deposition process. The light scattering surface 160s may increase a scattering characteristic of light passing through the scattering layer 160, and thus, may enhance a luminance viewing angle characteristic and light extraction efficiency of the plurality of subpixels SP and the display panel 10.

According to an embodiment of the invention, the scattering layer 160 may have a tetraphenylethylene (TPE) molecular structure, but is not limited thereto.

The scattering layer 160 according to an exemplary embodiment may have a molecular structure of tetraphenylethylene including four aromatic rings and four rotated aromatic rings as in the following Chemical Formula 1.

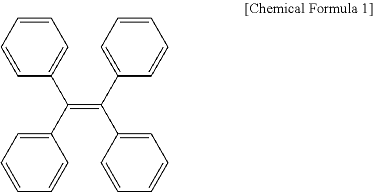 [SMILES: c1ccc(C(=C(c2ccccc2)c2ccccc2)c2ccccc2)cc1]

The scattering layer 160 according to an exemplary embodiment may have a molecular structure of tetraphenylethylene including five aromatic rings and two rotated aromatic rings as in the following Chemical Formula 2.

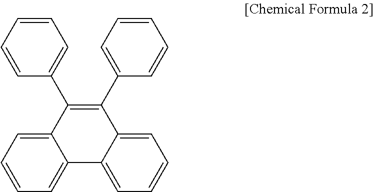 [SMILES: c1ccc(-c2c(-c3ccccc3)c3ccccc3c3ccccc23)cc1]

The scattering layer 160 according to an exemplary embodiment may have a molecular structure of tetraphenylethylene including four aromatic rings and two rotated aromatic rings as in the following Chemical Formula 3.

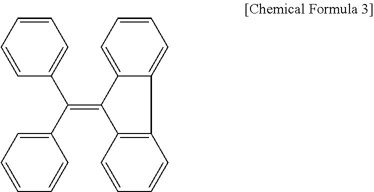 [SMILES: c1ccc(C(=C2c3ccccc3-c3ccccc32)c2ccccc2)cc1]

The scattering layer 160 according to an exemplary embodiment may have a molecular structure of tetraphenylethylene (TPE) including four aromatic rings and two rotated aromatic rings as in the following Chemical Formula 4.

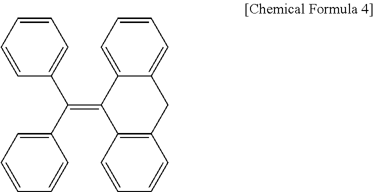 [SMILES: c1ccc(C(=C2c3ccccc3Cc3ccccc32)c2ccccc2)cc1]

The scattering layer 160 according to an exemplary embodiment may include bathocuproine (BCP) as in the following Chemical Formula 5. For example, bathocuproine (BCP) may be a diazapolycyclic aromatic compound and may be 2,9-dimethyl-4,7-diphenyl-1,10-phenanthroline (C₂₄H₂₀N₂), but is not limited thereto.

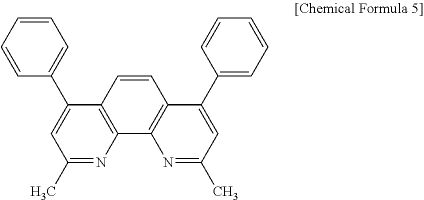 [SMILES: Cc1cc(-c2ccccc2)c2ccc3c(-c4ccccc4)cc(C)nc3c2n1]

The scattering layer 160 according to an exemplary embodiment may include triphenylamine derivatives (TPA derivatives or TPD) as in the following Chemical Formula 6. For example, the triphenylamine derivatives (TPD) may be an aromatic amine compound and may be N,N′-diphenyl-N,N′-bis(3-methylphenyl)-[1,1′-biphenyl]-4,4′-diamine (C₃₈H₃₂N₂), but is not limited thereto.

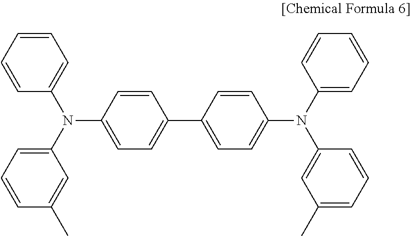 [SMILES: Cc1cccc(N(c2ccccc2)c2ccc(-c3ccc(N(c4ccccc4)c4cccc(C)c4)cc3)cc2)c1]

The scattering layer 160 according to an exemplary embodiment may include bathophenanthroline (BPhen) as in the following Chemical Formula 7. For example, bathophenanthroline (BPhen) may be an aromatic dimer compound and may be 4,7-diphenyl-1,10-phenanthroline (C₂₄H₁₆N₂), but is not limited thereto.

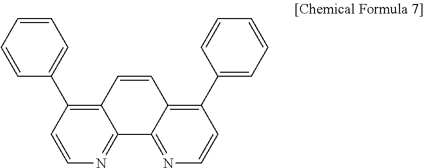 [SMILES: c1ccc(-c2ccnc3c2ccc2c(-c4ccccc4)ccnc23)cc1]

The scattering layer 160 according to an exemplary embodiment may include perylene derivatives as in the following Chemical Formula 8. For example, the perylene derivatives may be an aromatic hydrocarbon compound and may be N,N′-ditridecylperylene-3,4,9,10-tetracarboxylic diimide (PTCDI-C₁₃H₂₇ or C₅₀H₆₂N₂O₄), but is not limited thereto.

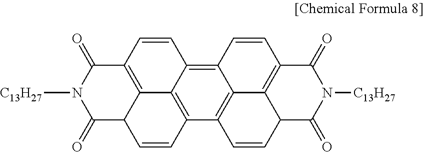

According to an exemplary embodiment, the scattering layer 160 may include pentacene derivatives as in the following Chemical Formula 9. For example, the pentacene derivatives may be a polycyclic aromatic hydrocarbon compound and may be 6,13-diphenylpentacene (C₂₂H₁₄), but is not limited thereto.

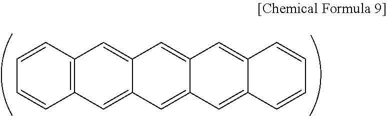

The scattering layer 160 according to an exemplary embodiment of the invention may include at least one of bathocuproine, triphenylamine derivatives, bathophenanthroline, perylene derivatives, and pentacene derivatives, but is not limited thereto.

According to an embodiment of the invention, the emission part EP may be disposed on the scattering layer 160. In the emission area EA and the non-emission area NEA, the emission part EP may have a shape corresponding to a surface shape of the scattering layer 160. The emission part EP may have a shape which conforms to the surface of the scattering layer 160 in an entire region of the display area AA or a surface shape of the light scattering surface 160s. For example, the hole functional layer HFL of the emission part EP may have a shape corresponding to the surface shape of the light scattering surface 160s. The emission layer EL of the emission part EP may have a shape corresponding to a surface shape of the hole functional layer HFL. The electron functional layer EFL of the emission part EP may have a shape corresponding to a surface shape of the organic emission layer EL.

According to an embodiment of the invention, the second electrode E2 may be disposed on the emission part EP. Because the emission part EP may have a shape corresponding to the surface shape of the scattering layer 160, the second electrode E2 disposed on the emission part EP may have a shape corresponding to the surface shape of the emission part EP.

The light emitting display apparatus, the display panel 10, and the sub-pixel SP according to an embodiment of the invention may further include a bank insulation layer 140.

The bank insulation layer 140 is disposed on the overcoat layer 130 and may be configured to define an emission area EA of each of the plurality of sub-pixels SP disposed in the display area AA. The bank insulation layer 140 may be disposed in the non-emission area NEA of each of the plurality of sub-pixels SP to define an emission area EA of each of the plurality of sub-pixels SP.

The bank insulation layer 140 may be configured to cover an edge portion of the first electrode E1. The bank insulation layer 140 may be configured to cover the second region E1p of the first electrode E1. For example, the bank insulation layer 140 may have a mesh shape. Accordingly, a first region, except the second region E1p), of the first electrode E1 may be defined as the emission area EA of the subpixel SP. For example, the bank insulation layer 140 may include a black material, a light blocking material, or a light absorbing material. For example, the bank insulation layer 140 may include a material which absorbs a specific wavelength.

According to an embodiment of the invention, a preprocessing step for the surface treatment of the first electrode E1 may be performed after a process of forming the bank insulation layer 140, but is not limited thereto. Since the first region of the first electrode E1 may not be covered by the bank insulation layer 140, the first region of the first electrode E1 may include the surface modification layer E1r on which surface treatment has been performed. On the other hand, because the second region E1p of the first electrode E1 may be covered by the bank insulation layer 140, the second region E1p of the first electrode E1 may not include the surface modification layer E1r on which surface treatment is performed. The second region E1p of the first electrode E1 may be a flat portion.

According to an embodiment of the invention, in the non-emission area NEA of each of the plurality of subpixels SP, the scattering layer 160 may be disposed to cover the bank insulation layer 140 and may have a surface shape which differs from that of the bank insulation layer 140. For example, in the non-emission area NEA of each of the plurality of subpixels SP, the scattering layer 160 may include the light scattering surface 160s and may directly contact the upper surface 140s of the bank insulation layer 140. For example, in the non-emission area NEA of each of the plurality of subpixels SP, the scattering layer 160 may include a concave-convex structure, and the upper surface 140s of the bank insulation layer 140 may include a flat surface structure. For example, a surface roughness of the scattering layer 160 on the bank insulation layer 140 may be greater than that of the bank insulation layer 140.

A protective layer 170 may be disposed to seal the light emitting device layer EDL. The protective layer 170 may be configured to prevent water or oxygen from penetrating into the light emitting device layer EDL and cover and prevent a flow of particles therein. The protective layer 170 may be disposed on and cover the second electrode E2. For example, the protective layer 170 may cover the entire second electrode E2. The protective layer 170 may be disposed on and cover the scattering layer 160. For example, the protective layer 170 may be an encapsulation layer or an encapsulation part.

The protective layer 170 according to an embodiment may include one or more inorganic encapsulation layers and one organic encapsulation layer. For example, the protective layer 170 may include a first encapsulation layer 171, a second encapsulation layer 172, and a third encapsulation layer 173. The first encapsulation layer 171 may be disposed on the second electrode E2.

The first encapsulation layer 171 may seal the light emitting device layer EDL and cover the scattering layer 160. The first encapsulation layer 171 may be an inorganic encapsulation layer including an inorganic material.

The second encapsulation layer 172 may be disposed on the first encapsulation layer 171. The second encapsulation layer 172 may be disposed on the first encapsulation layer 171 in the display area AA of the substrate 100. The second encapsulation layer 172 may be an organic encapsulation layer including an organic material. Overflowing of the second encapsulation layer 172 may be prevented by a dam which is disposed at an edge portion of the substrate 100.

The third encapsulation layer 173 may be disposed on the second encapsulation layer 172 and cover the second encapsulation layer 172. The third encapsulation layer 173 may cover the second encapsulation layer 172 and may be disposed on the first encapsulation layer 171 in the non-display area IA of the substrate 100. The third encapsulation layer 173 may be an inorganic encapsulation layer including an inorganic material. The third encapsulation layer 173 may be disposed in the display area AA to surround the second encapsulation layer 172 along with the first encapsulation layer 171. For example, the second encapsulation layer 172 may be disposed between the first encapsulation layer 171 and the third encapsulation layer 173 each surrounded by a dam in the display area AA of the substrate 100.

Each of the first encapsulation layer 171 and the third encapsulation layer 173 may extend from the display area AA of the substrate 100 to a partial region of the non-display area IA adjacent to an end of the substrate 100. For example, in the non-display area IA illustrated in FIG. 1, the third encapsulation layer 173 may be disposed to directly contact the first encapsulation layer 171.

The light emitting display apparatus according to an embodiment of the invention may further include an optical film 400.

The optical film 400 may include an anti-reflection layer attached to a first surface 100a of the substrate 100. For example, the optical film 400 may include a polarization film or a circular polarization film, but is not limited thereto. The optical film 400 may be attached to the first surface 100a of the substrate 100 by an adhesive member.

The light emitting display apparatus according to an embodiment of the invention may further include a cover window 300. The cover window 300 may protect the display panel 10. The cover window 300 may be disposed on the protective layer 170. The cover window 300 may be larger than the display panel 10 and may include a transparent material, but is not limited thereto. For example, the cover window 300 may include a plastic material or a glass material.

According to an embodiment of the invention, the light emitting display apparatus may include the scattering layer 160 disposed in the light emitting device layer EDL, and thus, a micro-cavity distance may be changed. For example, because the light emitting display apparatus may include the scattering layer 160 disposed in the light emitting device layer EDL, a micro-cavity effect may be reduced, and thus, a front luminance may decrease, and a luminance viewing angle may be increased by the scattering layer 160.

The light emitting display apparatus according to an embodiment of the invention may include the scattering layer 160 including the light scattering surface 160s, and thus, a scattering characteristic of light emitted from the light emitting device layer EDL may be increased by the scattering layer 160, thereby increasing the luminance viewing angle characteristic and may increase the light extraction efficiency of the plurality of subpixels SP and the display panel 10. Accordingly, a power consumption of the light emitting display apparatus according to an embodiment of the invention may be reduced through low power driving based on the increased light extraction efficiency.

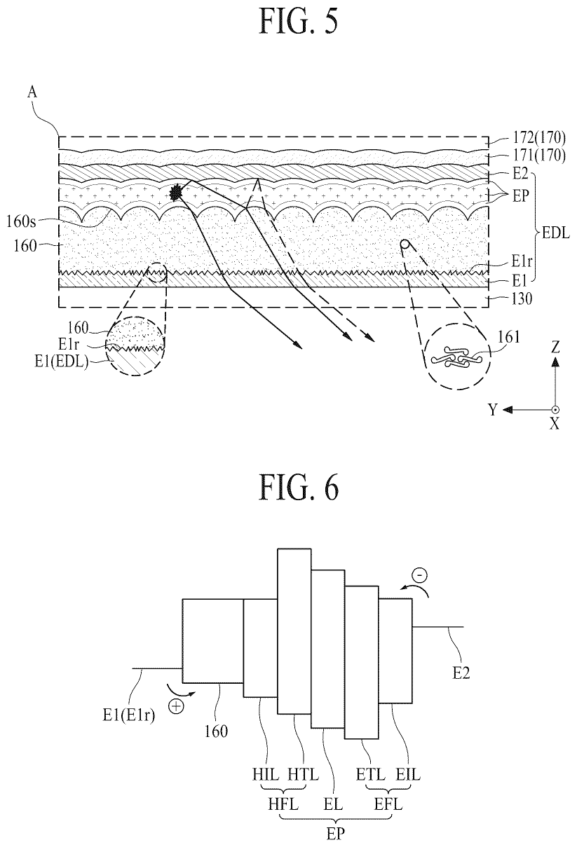

FIG. 5 is an enlarged view of a portion A illustrated in FIG. 3. FIG. 5 is a diagram for describing the first electrode E1 and the scattering layer 160 described above with reference to FIG. 3.

Referring to FIG. 3 and FIG. 5, in the light emitting display apparatus according to an embodiment of the invention, the scattering layer 160 may be uniformly deposited on a surface of the first electrode E1, particularly on the surface modification layer E1r thereof. The scattering layer 160 may be deposited on the surface modification layer E1r having a surface energy which is increased by plasma treatment, and thus, may be stably deposited on the first electrode E1. For example, by increasing the surface energy of the first electrode E1 of the light emitting device layer EDL, the scattering layer 160 may be stably deposited on the first electrode E1, and adhesion between the scattering layer 160 and the first electrode E1 may be improved.

According to an embodiment of the invention, transparent conductive oxide may have a surface energy in a range of about 30 mN/m to 50 mN/m. For example, the surface energy of the first electrode E1 may increase through surface modification (for example, surface roughness, adhesive force, hydrophilicity, physical surface modification, chemical surface modification, etc.) of the first electrode E1 based on a preprocessing process (for example, an oxygen plasma process). Even when the first electrode E1 includes a material having low surface energy, a preprocessing treatment may increase the surface energy of the first electrode E1. Accordingly, the scattering layer 160 may be stably deposited on the surface of the first electrode E1.

According to an embodiment of the invention, when the first electrode E1 includes a metal material such as transparent conductive oxide, an oxygen plasma process of irradiating oxygen plasma onto a surface of transparent conductive oxide for tens of seconds or more (for example, 20 sec or more) may be additionally performed. For example, the first electrode E1 including transparent conductive oxide may have a surface energy in a range of 800 mN/m to 1200 mN/m, based on the oxygen plasma process, but is not limited thereto.

When an oxygen plasma process is performed on the surface of the first electrode E1 including transparent conductive oxide, the first electrode E1 may include the surface modification layer E1r having a surface roughness. Accordingly, when the scattering layer 160 is formed on the oxygen plasma-treated first electrode E1 the scattering layer 160 material may be stably deposited on the surface modification layer E1r of the first electrode E1 having a high surface energy, and thus, the scattering layer 160 including the light scattering surface 160s may be stably formed on the first electrode E1.

As shown in FIG. 5, light generated in the emission part EP may be emitted toward the first electrode E1 and the second electrode E2, and a portion of the light emitted toward the second electrode E2 may be reflected by the second electrode E2 back toward the first electrode E1. The emitted and reflected light may propagate through the scattering layer 160 disposed on the surface of the first electrode E1. As the light passes through the scattering layer 160, the light may be scattered by molecular structures 161 included therein, such that an optical path of the light is changed.

FIG. 6 is a diagram illustrating an energy level diagram of a light emitting display apparatus according to an embodiment of the invention, according to an embodiment described above with reference to FIG. 3, FIG. 4, and FIG. 5. Hereinafter, therefore, only different elements will be described, and the same elements will be briefly described, or their descriptions may be omitted.

Referring to FIG. 6, in the light emitting display apparatus according to an embodiment of the invention, when positive (+) and negative (−) voltages are respectively applied to the first electrode E1 and the second electrode E2, a hole from the first electrode E1 and an electron from the second electrode E2 may be transported to the emission part EP to generate an exciton, and light may be generated when the exciton is shifted from an excited state to a ground state.

The light emitting display apparatus according to an embodiment of the invention may include the light emitting device layer EDL and the scattering layer 160. The light emitting device layer EDL may include the first electrode E1, the emission part EP, and the second electrode E2. The emission part EP may include an emission layer or an organic emission layer EL, the hole functional layer HFL, and the electron functional layer EFL. The emission layer EL may be disposed between the hole functional layer HFL and the electron functional layer EFL. The emission layer EL may be a layer where a hole and an electron are recombined to emit light.

The hole functional layer HFL may be disposed between the first electrode E1 and the emission layer EL, and may be disposed between the scattering layer 160 and the organic emission layer EL. The hole functional layer HFL may include one or more of a hole injection layer HIL and a hole transport layer HTL. For example, the hole functional layer HFL may include the hole transport layer HTL. As another example, the hole functional layer HFL may include the hole injection layer HIL and the hole transport layer HTL.

The electron functional layer EFL may be disposed between the second electrode E2 and the organic emission layer EL. The electron functional layer EFL may include one or more of an electron injection layer EIL and an electron transport layer ETL. For example, the electron functional layer EFL may include the electron transport layer ETL. As another example, the electron functional layer EFL may include the electron injection layer EIL and the electron transport layer ETL.

The scattering layer 160 may be disposed between the first electrode E1 and the emission part EP. The scattering layer 160 may be disposed between the first electrode E1 and the hole functional layer HFL of the emission part EP.

According to an embodiment of the invention, the scattering layer 160 may include a material similar to that of the hole functional layer HFL, to facilitate the movement of holes (+). For example, when the hole functional layer HFL includes the hole transport layer HTL, the scattering layer 160 may include a material similar to that of the hole transport layer HTL or a material having a highest occupied molecular orbital (HOMO) energy level, similar to that of the hole transport layer HTL, to facilitate the movement of holes (+). For example, when the hole functional layer HFL includes the hole injection layer HIL and the hole transport layer HTL, the scattering layer 160 may include a material similar to that of the hole injection layer HIL or a material having a HOMO energy level similar to that of the hole injection layer HIL to facilitate the movement of holes (+).

According to an embodiment of the invention, a plasma treatment may be performed on an upper surface of the first electrode E1 to configure the surface modification layer E1r. Accordingly, the surface roughness of the first electrode E1 may increase, and an adhesion area may increase. Accordingly, an adhesive force between the first electrode E1 and the scattering layer 160 may be enhanced, facilitating the movement of holes.

According to an embodiment of the invention, the upper surface of the first electrode E1 may be plasma-treated, and the scattering layer 160 may be disposed on the first electrode E1, and thus, a work function of the scattering layer 160 may be adjusted to be similar to that of the hole functional layer HFL. For example, the upper surface of the first electrode E1 may be plasma-treated, and the scattering layer 160 may be disposed on the first electrode E1, and thus, a HOMO energy level of the scattering layer 160 may have a value between the work function of the first electrode E1 and a HOMO energy level of the hole functional layer HFL. For example, the work function of the first electrode E1 may be 5.0 eV, the HOMO energy level of the scattering layer 160 may be 5.2 eV, and a HOMO energy level of the hole injection layer HIL among the hole functional layers HFL may be 5.4 eV.

Accordingly, the upper surface of the first electrode E1 may be plasma-treated and the scattering layer 160 may be disposed on the first electrode E1, and thus, the movement of holes therein may be facilitated compared to when the scattering layer 160 is not plasma-treated, and a light emitting display apparatus may be driven without a degradation in a display panel even when a driving voltage is equally applied.

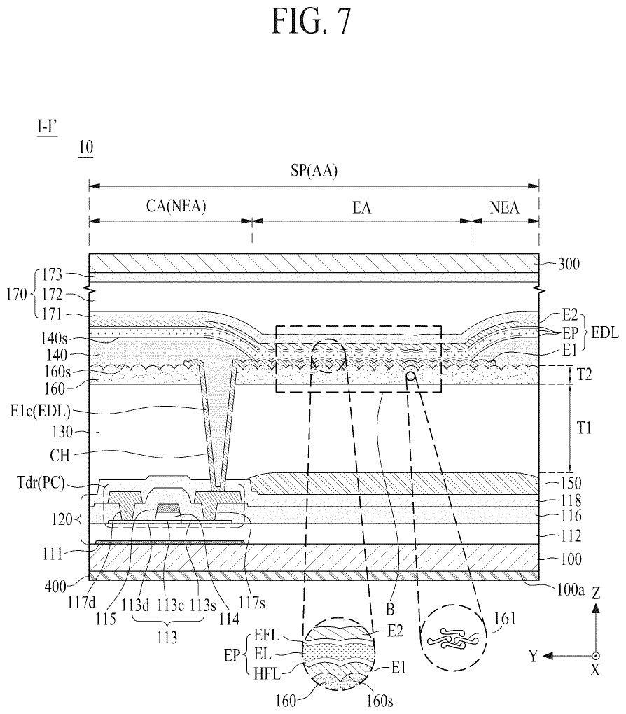

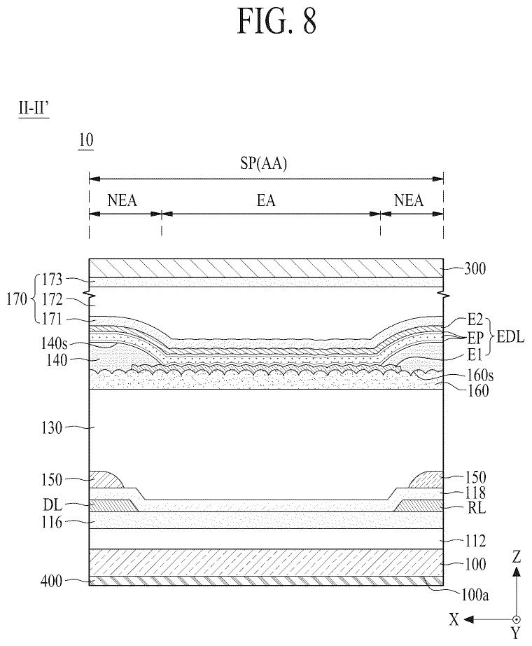

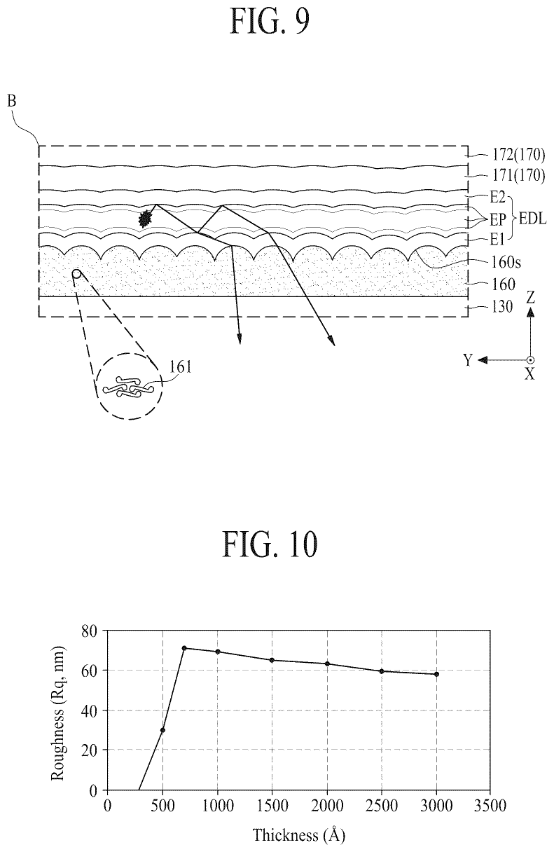

FIG. 7 is a cross-sectional view illustrating an embodiment taken along line I-I′ of FIG. 2. FIG. 8 is a cross-sectional view illustrating an embodiment taken along line II-II′ of FIG. 2. FIG. 9 is an enlarged view of a portion B illustrated in FIG. 7. FIG. 7, FIG. 8, and FIG. 9 relate to an embodiment of the invention, and except for a scattering layer being disposed outside a light emitting device layer, FIG. 7, FIG. 8, and FIG. 9 may be substantially the same as the embodiments of the invention described above. Hereinafter, only different elements will be described, and the same elements will be briefly described, or their descriptions may be omitted.

Referring to FIG. 7, FIG. 8, and FIG. 9, the scattering layer 160 according to the present embodiment may be disposed outside the light emitting device layer EDL. The scattering layer 160 may be configured outside the light emitting device layer EDL to increase a scattering characteristic of light emitted from the emission part EP. The scattering layer 160 may be disposed between the overcoat layer 130 and the light emitting device layer EDL. Accordingly, the luminance viewing angle characteristics and light extraction efficiency of the plurality of subpixels SP or the display panel 10 may be improved.

According to the present embodiment, the scattering layer 160 may be disposed on the overcoat layer 130, and between the overcoat layer 130 and the first electrode E1. The scattering layer 160 may contact an upper surface of the overcoat layer 130 or a lower surface of the first electrode E1.

According to the present embodiment, the scattering layer 160 may be formed of a material which differs from that of the overcoat layer 130 and may be formed to have a second thickness T2 which is relatively less than the first thickness T1 of the overcoat layer 130. For example, the second thickness T2 of the scattering layer 160 may be less than 10% of the first thickness T1 of the overcoat layer 130. For example, the overcoat layer 130 may be formed to have the thickness T1 of several micrometers (μm). For example, the scattering layer 160 may be formed to have the thickness T2 in a range of 500 Å to 3000 Å.

The light scattering surface 160s of the scattering layer 160 may be formed using only a deposition process without an additional separate patterning process, and thus, a roughness of the light scattering surface 160s may be determined based on the thickness T2 of the scattering layer 160. For example, when the roughness of the light scattering surface 160s is formed in a plurality of curved shapes, a size of the plurality of curved shapes may be determined based on the thickness T2 of the scattering layer 160.

The scattering layer 160 according to an embodiment of the invention may have a thickness of 500 Å or more. For example, when the thickness of the scattering layer 160 is less than 500 Å, a non-deposition phenomenon of the scattering layer 160 may occur, and due to this, luminance viewing angle characteristics may be reduced. For example, with respect to a luminance viewing angle of 45 degrees for the plurality of subpixels SP, the scattering layer 160 may have a thickness of 3000 Å or less, based on the material cost and productivity. For example, when the thickness of the scattering layer 160 is greater than 680 Å, the roughness of the light scattering surface 160s may decrease. Accordingly, when the thickness of the scattering layer 160 is greater than 3000 Å, the roughness of the light scattering surface 160s may decrease. For example, the thickness of the scattering layer 160 according to an embodiment of the invention may be in a range of 680 Å to 2000 Å, but is not limited thereto. For example, in order to implement luminance viewing angle characteristics of the plurality of subpixels SP by 70% or more, the thickness of the scattering layer 160 may be optimized to be in a range of 680 Å to 2,000 Å.

The surface roughness of the scattering layer 160 according to an embodiment of the invention may be tens of nm or more. For example, the surface roughness of the scattering layer 160 may be 10 nm or more. For example, the light scattering surface 160s of the scattering layer 160 may have a roughness in a range of 30 nm to 71 nm. For example, in order to implement a luminance viewing angle of 70% or more for white (W), and because a luminance viewing angle for green (G) should be 60% or more, the roughness Rq of the light scattering surface 160s of the scattering layer 160 may be at least 63 nm, but is not limited thereto.

According to an embodiment of the invention, the scattering layer 160 may be formed to include the light scattering surface 160s through only a deposition process of a material without an additional separate patterning process. For example, the scattering layer 160 may be formed by a thermal evaporation process, but is not limited thereto. For example, because the scattering layer 160 is formed to include the light scattering surface 160s through only a deposition process of a material, the scattering layer 160 may be distinguished process-wise, structurally, and materially from a light scattering surface (such as a microlens) which is directly formed in a portion of the overcoat layer 130 or in a separate organic material layer disposed on the overcoat layer 130 through a separate patterning or ashing process using a photoresist.

According to an embodiment of the invention, the light emitting device layer EDL disposed in the emission area EA of each of the plurality of subpixels SP may have a shape corresponding to the surface shape of the light scattering surface 160s of the scattering layer 160. For example, the light emitting device layer EDL may include a surface shape which conforms to the surface of the light scattering surface 160s of the scattering layer 160. For example, in each of the plurality of subpixels SP, a first region of the light emitting device layer EDL disposed in the emission area EA may include a surface shape, differing from a second region, of the light emitting device layer EDL disposed in the non-emission area NEA. For example, in each of the plurality of subpixels SP, the surface shape of the first region of the light emitting device layer EDL disposed in the emission area EA may include a shape corresponding to the surface shape of the light scattering surface 160s of the scattering layer 160, and the surface shape of the second region of the light emitting device layer EDL disposed in the non-emission area NEA may include a shape corresponding to the surface shape of the bank insulation layer 140.

The light emitting device layer EDL may include the first electrode E1, the emission part EP, and the second electrode E2, which are stacked and disposed on the overcoat layer 130.

The first electrode E1 may be disposed on and contact the scattering layer 160. The first electrode E1 may have a shape corresponding to the surface of the scattering layer 160 or the light scattering surface 160s. The first electrode E1 may be connected to the source electrode 117s of the driving thin film transistor Tdr through a contact hole CH passing through the overcoat layer 130 and the scattering layer 160.

According to an embodiment of the invention, a surface shape of the first region of the first electrode E1 disposed in the emission area EA may include a shape conforming to the light scattering surface 160s, and the second region of the first electrode E1 disposed in the non-emission area NEA may include a contact portion E1c connected to the driving thin film transistor Tdr through the contact hole CH and may include a surface shape corresponding to the contact hole CH and a peripheral area of the contact hole CH.

The emission part EP may be disposed between the first electrode E1 and the second electrode E2. The emission part EP may directly contact the first electrode E1 except for the end portion thereof, and may directly contact a portion of the bank insulation layer 140 covering the end portion of the first electrode E1. Because the first electrode E1 may have a shape corresponding to the surface shape of the scattering layer 160, the emission part EP disposed on the first electrode E1 may have a shape corresponding to the surface shape of the first electrode E1.

According to an embodiment of the invention, in the non-emission area NEA of each of the plurality of subpixels SP, the scattering layer 160 may be covered by the bank insulation layer 140 and may have a surface shape which differs from that of the bank insulation layer 140. For example, in the non-emission area NEA of each of the plurality of subpixels SP, the scattering layer 160 may include the light scattering surface 160s covered by the bank insulation layer 140, and may have a concave-convex structure, and the upper surface 140s of the bank insulation layer 140 may have a substantially flat structure. For example, the surface roughness of the scattering layer 160 under the bank insulation layer 140 may be greater than that of the bank insulation layer 140.

According to an embodiment of the invention, in the emission area EA of each of the plurality of subpixels SP, the emission part EP may have a shape corresponding to the surface shape of the scattering layer 160. The emission part EP may have a shape which conforms to the surface shape of the scattering layer 160 or the light scattering surface 160s. For example, the hole functional layer HFL of the emission part EP may have a shape corresponding to the surface shape of the light scattering surface 160s. The emission layer EL of the emission part EP may have a shape corresponding to the surface shape of the hole functional layer HFL. The electron functional layer EFL of the emission part EP may have a shape corresponding to the surface shape of the organic emission layer EL.

According to an embodiment of the invention, in the non-emission area NEA of each of the plurality of subpixels SP, the emission part EP may have a shape corresponding to a surface shape of the bank insulation layer 140 or the bank insulation layer 140. For example, the hole functional layer HFL of the emission part EP may have a shape corresponding to the surface shape of the bank insulation layer 140. The organic emission layer EL of the emission part EP may have a shape corresponding to the surface shape of the hole functional layer HFL. The electron functional layer EFL of the emission part EP may have a shape corresponding to the surface shape of the organic emission layer EL.

According to an embodiment of the invention, in the non-emission area NEA of each of the plurality of subpixels SP, the scattering layer 160 may have a concave-convex structure, the upper surface 140s of the bank insulation layer 140 may have a flat surface structure, and the emission part EP may have a surface shape corresponding to the flat surface structure of the bank insulation layer 140. For example, in each of the plurality of subpixels SP, a first region of the emission part EP may have a surface shape which differs from that of a second region of the emission part EP. For example, the first region of the emission part EP disposed in the emission area EA of each of the plurality of subpixels SP may have a concave-convex structure, and the second region of the emission part EP disposed in the non-emission area NEA of each of the plurality of subpixels SP may have a flat surface structure. For example, in each of the plurality of subpixels SP, the first region of the emission part EP may have a surface roughness which is relatively greater than that of the second region of the emission part EP.

The second electrode E2 may be disposed on the emission part EP. Because the emission part EP may have a shape corresponding to the surface shape of the scattering layer 160, the second electrode E2 disposed on the emission part EP may have a shape corresponding to the surface shape of the emission part EP.

According to an embodiment of the invention, the scattering layer 160 may be disposed outside the light emitting device layer EDL, such that a light scattering effect may be obtained while maintaining a micro-cavity length.

As shown in FIG. 9, light generated in the emission part EP may be emitted toward the first electrode E1 and the second electrode E2, and a portion of the light emitted toward the second electrode E2 may be reflected by the second electrode E2 back toward the first electrode E1. The emitted and reflected light may propagate through the scattering layer 160. As the light passes through the scattering layer 160, the light may be scattered by molecular structures 161 included therein, such that an optical path of the light is changed. As described above, the light emitting display apparatus according to an embodiment of the invention may include the scattering layer 160 including the light scattering surface 160s, and thus, a light-scattering characteristics of the light emitting device layer EDL may be increased by the scattering layer 160, thereby or enhancing the luminance viewing angle characteristics and light extraction efficiency of the plurality of subpixels SP or the display panel 10. Accordingly, a power consumption of the light emitting display apparatus according to an embodiment of the invention may be reduced through low power driving based on the increased light extraction efficiency.

FIG. 10 is a diagram illustrating a roughness of a light scattering surface with respect to a thickness of a scattering layer, in a light emitting display apparatus according to an embodiment of the invention.

Referring to FIG. 10, a roughness of a light scattering surface may increase as a thickness of a scattering layer decreases, and due to this, a size of a plurality of curved shapes formed on the light scattering surface may also increase. However, as a thickness T of the scattering layer decreases to less than 500 Å, the roughness Rq of the light scattering surface may rapidly decrease, and due to this, the plurality of curved shapes formed on the light scattering surface may also be rapidly reduced in size. For example, as a deposition force is rapidly reduced from where the thickness T of the scattering layer is less than 500 Å, the surface roughness of the scattering layer may not be formed or may be fine, and thus, it may be difficult to expect a light scattering effect.

Accordingly, the scattering layer 160 according to an embodiment of the invention may have a thickness in a range of 500 Å to 1500 Å. For example, when the thickness of the scattering layer 160 is less than 500 Å, a non-deposition phenomenon of the scattering layer 160 may occur, and due to this, luminance viewing angle characteristics may be reduced. For example, when the thickness T of the scattering layer 160 is greater than 1500 Å, a transfer distance of a hole may increase, and degradation of the light emitting device may occur. Therefore, the scattering layer 160 may have a thickness in a range of 500 Å to 1500 Å.

The following Table 1 shows a half luminance angle and Rtings score according to a plasma treatment time in the light emitting display apparatus according to an embodiment of the invention.

The half luminance angle represents an angle which allows maximum luminance measured from the front (for example, 0 degrees) to decrease by half (for example, 50%), and the spec needed for a user is 65 degrees.

The Rtings score represents a viewing-angle performance index for a display device. To enhance the viewing angle characteristics of the light emitting display apparatus with respect to the Rtings score, values of brightness loss BL, color washout CW, and color shift CS may be controlled. For example, the brightness loss BL, color washout CW, and color shift CS may each be converted into 10-point scale with respect to the Rtings score.

Main factors which determine the values of brightness loss BL, color washout CW, and color shift CS may respectively be chroma (for example, color coordinate change and half luminance angle), hue (for example, color coordinate change), and half luminance angle. For example, the amount of change in chroma and the amount of change in hue may be simulated by fixing luminance and varying color coordinates.

In Table 1, values outside the parentheses represent Rtings scores obtained by converting the degrees of brightness loss BL, color washout CW, and color shift CS into a 10-point scale, while the values inside the parentheses represent the corresponding degrees of brightness loss BL, color washout CW, and color shift CS.

According to an embodiment of the invention, specs of brightness loss BL, color washout CW, and color shift CS needed for the user are greater than or equal to 60 degrees, 49 degrees, and 46 degrees, respectively. When the values of brightness loss BL, color washout CW, and color shift CS are greater than or equal to 60 degrees, 49 degrees, and 46 degrees, respectively, the values of brightness loss BL, color washout CW, and color shift CS may be converted into a 10-point scale.

TABLE 1

| Plasma Treatment Time (sec) | | | 20 s | 40 s | 60 s |
|---|---|---|---|---|---|
| Half Luminance Angle | | Spc. 65° | 90° | 90° | 90° |
| Rtings | BL | Spc. 9.0(60°) | 10.0(70°) | 10.0(70°) | 10.0(70°) |
| | CS | Spc. 7.9(49°) | 7.2(44°) | 6.7(41°) | 8.1(50°) |
| | CW | Spc. 7.6(46°) | 10.0(70°) | 10.0(70°) | 10.0(70°) |

Referring to Table 1, when plasma treatment has been performed on the first electrode E1, the values of half luminance angle, luminance loss BL, and color washout CW satisfying desired conditions have been measured for 20 sec or more. When plasma treatment has been performed for 60 sec, the value of color shift CS represents a value of 8.1 points or more. Accordingly, when plasma treatment has been performed for 60 sec, it may be confirmed that the values of half luminance angle, luminance loss BL, color washout CW, and color shift CS satisfy conditions needed for the user.

According to an embodiment of the invention, when plasma treatment has been performed on the first electrode E1, it may be confirmed that the values of half luminance angle brightness loss BL, color washout CW, and color shift CS with respect to 60 sec satisfy desired conditions. According to one or more embodiments of the present disclosure, the scattering layer 160 may be disposed outside or in the light emitting device layer EDL, thereby providing a light emitting display apparatus where a luminance viewing angle characteristic and light extraction are enhanced.

According to one or more embodiments of the invention, a light emitting display apparatus where power consumption may be reduced through low power driving based on an increase in the amount of light extraction may be provided. Accordingly, the light emitting display apparatus according to one or more embodiments of the invention may implement environment social governance (ESG), based on an effect of reducing power consumption.

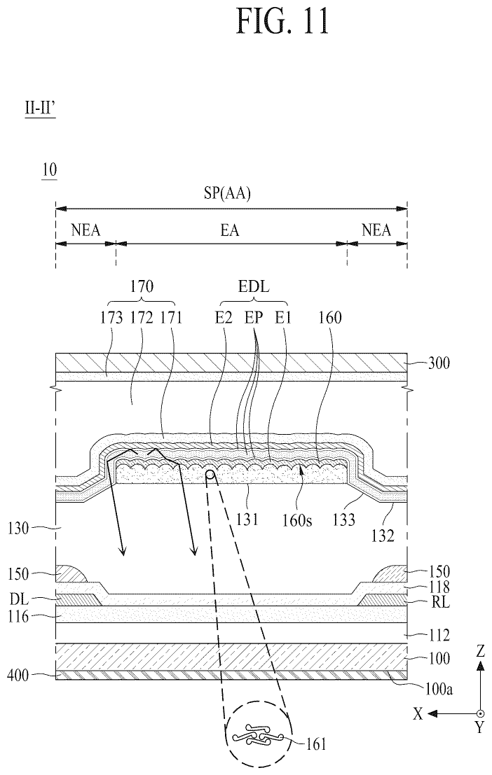

FIG. 11 is a cross-sectional view illustrating an embodiment taken along line II-II′ of FIG. 2. Except for an overcoat layer including a flat surface, an inclined surface, and a scattering layer selectively disposed in an emission area, the embodiment illustrated in FIG. 11 may be the same as the embodiment of the invention described above with reference to FIG. 7, FIG. 8 and FIG. 9. The cross-sectional view taken along line I-I′ in a light emitting display apparatus according to an embodiment described with reference to FIG. 11 may be substantially the same as FIG. 7. Hereinafter, only different elements will be described, and the same elements will be briefly described, or their descriptions may be omitted.

Referring to FIG. 7 and FIG. 11, a light emitting display apparatus 10 according to an embodiment of the invention may include the substrate 100 including the plurality of subpixels SP including the emission area EA and the non-emission area NEA, a thin film transistor Tdr in the non-emission area NEA, the overcoat layer 130 disposed in the emission area EA and the non-emission area NEA and covering the thin film transistor Tdr, the scattering layer 160 on the overcoat layer 130, and the light emitting device layer EDL including the first electrode E1 on the scattering layer 160 and connected to the thin film transistor Tdr, the emission part EP on the first electrode E1, and the second electrode E2 on the emission part EP. The scattering layer 160 may include the light scattering surface 160s formed based on an intermolecular stack structure.

The overcoat layer 130 may be disposed in the emission area EA and the non-emission area NEA on the substrate 100. According to an embodiment of the invention, the overcoat layer 130 may include a first flat surface 131, a second flat surface 132, and an inclined surface 133.

The first flat surface 131 may be disposed in the emission area EA. The first flat surface 131 may overlap the emission area EA. The first flat surface 131 may not be disposed in the non-emission area NEA. The first flat surface 131 may be a region of the overcoat layer 130 having a maximum thickness. The first flat surface 131 may be a protrusion region which protrudes from the second flat surface 132. The first flat surface 131 may overlap the scattering layer 160 and the light emitting device layer EDL. The first flat surface 131 may contact the scattering layer 160. An uppermost surface of the first flat surface 131 may directly contact a lowermost surface of the scattering layer 160.

The second flat surface 132 may be disposed in the non-emission area NEA, and may overlap the non-emission area NEA. The second flat surface 132 may not be disposed in the emission area EA. The second flat surface 132 may be a region, having a minimum thickness, of the overcoat layer 130. A thickness of the second flat surface 132 may be less than that of the first flat surface 131. The second flat surface 132 may be disposed lower than the first flat surface 131 with respect to the substrate 100. A distance to the second flat surface 132 from the substrate 100 may be less than a distance to the first flat surface 131 from the substrate 100.

The second flat surface 132 may not overlap the scattering layer 160 and the first electrode E1. The scattering layer 160 and the first electrode E1 may not be disposed on the second flat surface 132. The second flat surface 132 may overlap the emission part EP and the second electrode E2 in the light emitting device layer EDL. The second flat surface 132 may contact the emission part EP. An uppermost surface of the second flat surface 132 may directly contact a lowermost surface of the emission part EP. The inclined surface 133 may be disposed in the non-emission area NEA.

The inclined surface 133 may connect the first flat surface 131 to the second flat surface 132. The inclined surface 133 may extend from the second flat surface 132 disposed in the non-emission area NEA and may be connected to the first flat surface 131 disposed in the emission area EA. Based on a step height between the first flat surface 131 and the second flat surface 132, the inclined surface 133 may be inclined.

The inclined surface 133 may be formed to extract light which is emitted from the emission area EA and is then dissipated in a waveguide mode. For example, light emitted from the emission area EA and dissipated in the waveguide mode may be extracted toward the front through the inclined surface 133. For example, the waveguide mode may be defined as light which does not travel to the outside due to total internal reflection in a device and is dissipated or absorbed in the middle of propagating along the inside of a layer like a waveguide.

According to an embodiment of the invention, as the inclined surface 133 is provided, light extraction efficiency and front luminance may be enhanced. The scattering layer 160 may have the same configuration and effect as the scattering layer described above with reference to FIG. 7, FIG. 8 and FIG. 9, except for a position thereof. Hereinafter, only different elements will be described, and the same elements will be briefly described, or their descriptions are omitted.

The scattering layer 160 may be disposed outside the light emitting device layer EDL. The scattering layer 160 may be configured outside the light emitting device layer EDL to increase a scattering characteristic of light emitted from the emission part EP. The scattering layer 160 may be disposed between the overcoat layer 130 and the light emitting device layer EDL.

According to an embodiment of the invention, the scattering layer 160 may be disposed in the emission area EA or may be disposed on the overcoat layer 130. The scattering layer 160 may be disposed between the overcoat layer 130 and the first electrode E1. The scattering layer 160 may be disposed on the first flat surface 131 of the overcoat layer 130. The scattering layer 160 may directly contact the first flat surface 131. The scattering layer 160 may contact an upper surface of the first flat surface 131. The scattering layer 160 may contact a lower surface of the first electrode E1.

The scattering layer 160 may not be disposed in the non-emission area NEA. The scattering layer 160 may not overlap the inclined surface 133 and the second flat surface 132. The scattering layer 160 may not be disposed on an upper surface of each of the inclined surface 133 and the second flat surface 132.

For example, when the scattering layer 160 is disposed on the inclined surface 133, light reflected from the inclined surface 133 may be scattered, and thus, the extraction efficiency of light emitted to the outside may be reduced.

According to an embodiment of the invention, the scattering layer 160 may be disposed on the first flat surface 131 in the emission area EA and may not disposed on the inclined surface 133, and thus, a light scattering effect may be selectively obtained, and an entire luminance viewing angle characteristic of a light emitting display apparatus may be enhanced.

According to an embodiment of the invention, the light emitting device layer EDL disposed in the emission area EA of each of the plurality of subpixels SP may include a shape corresponding to a surface shape of the light scattering surface 160s of the scattering layer 160. For example, the light emitting device layer EDL disposed in the emission area EA of each of the plurality of subpixels SP may include a surface shape which conforms to the surface shape of the light scattering surface 160s of the scattering layer 160.

The light emitting device layer EDL may include the first electrode E1, the emission part EP, and the second electrode E2, which are stacked on the overcoat layer 130. The first electrode E1 may be disposed on the scattering layer 160 or may contact the scattering layer 160. The first electrode E1 may contact the light scattering surface 160s of the scattering layer 160 on the scattering layer 160. The first electrode E1 may have a shape corresponding to the surface shape of the scattering layer 160 or the light scattering surface 160s.

The first electrode E1 may be disposed in the emission area EA. The first electrode E1 may not be disposed in the non-emission area NEA. The first electrode E1 may not be disposed on the inclined surface 133 and the second flat surface 132. The first electrode E1 may not overlap the inclined surface 133 and the second flat surface 132.

The emission part EP may be configured between the first electrode E1 and the second electrode E2. In the emission area EA, because the first electrode E1 has a conformal shape corresponding to the surface shape of the scattering layer 160, the emission part EP disposed on the first electrode E1 may include a conformal shape corresponding to the surface shape of the first electrode E1. The emission part EP may have a conformal shape which conforms to the surface shape of the first electrode E1. The emission part EP may have a conformal shape corresponding to the surface shape of the first electrode E1. For example, the hole functional layer HFL of the emission part EP may have a conformal shape corresponding to the surface shape of the first electrode E1. The emission layer EL of the emission part EP may have a conformal shape corresponding to a surface shape of the hole functional layer HFL. The electron functional layer EFL of the emission part EP may have a conformal shape corresponding to a surface shape of the organic emission layer EL.

In the non-emission area NEA, the emission part EP may be disposed on the inclined surface 133 and the second flat surface 132. In the non-emission area NEA, the emission part EP may contact the inclined surface 133 and the second flat surface 132. The emission part EP may have a shape corresponding to the inclined surface 133 and the second flat surface 132. For example, the hole functional layer HFL of the emission part EP may have a shape corresponding to a surface shape of each of the inclined surface 133 and the second flat surface 132. The organic emission layer EL of the emission part EP may have a shape corresponding to a surface shape of the hole functional layer HFL. The electron functional layer EFL of the emission part EP may have a shape corresponding to a surface shape of the organic emission layer EL.

The second electrode E2 may be disposed on the emission part EP. In the emission area EA, the emission part EP may have a shape corresponding to the surface shape of the scattering layer 160 or the first electrode E1, and thus, the second electrode E2 disposed on the emission part EP may have a shape corresponding to the surface shape of the emission part EP.

In the non-emission area NEA, the second electrode E2 may be disposed on the inclined surface 133 and the second flat surface 132. In the non-emission area NEA, the second electrode E2 may overlap the inclined surface 133 and the second flat surface 132. In the non-emission area NEA, because the emission part EP has a shape corresponding to the inclined surface 133 and the second flat surface 132, the second electrode E2 disposed on the emission part EP may have a shape corresponding to the surface shape of the emission part EP.

According to an embodiment of the invention, the scattering layer 160 may be disposed outside the light emitting device layer EDL, and thus, a light scattering effect may be obtained while maintaining a micro-cavity distance.

The light emitting display apparatus according to an embodiment of the invention may include the scattering layer 160 including the light scattering surface 160s, and thus, may increase a scattering characteristic of light emitted from the light emitting device layer EDL.

According to an embodiment of the invention, light extraction efficiency and front luminance may be enhanced due to the inclined surface 133, and simultaneously, the scattering layer 160 may not be disposed on the inclined surface 133 and may be disposed in the emission area EA, thereby enhancing the luminance viewing angle characteristic and light extraction efficiency of the plurality of subpixels SP or the display panel 10.

Accordingly, the power consumption of the light emitting display apparatus according to an embodiment of the invention may be reduced through low power driving based on an increase in the light extraction efficiency.

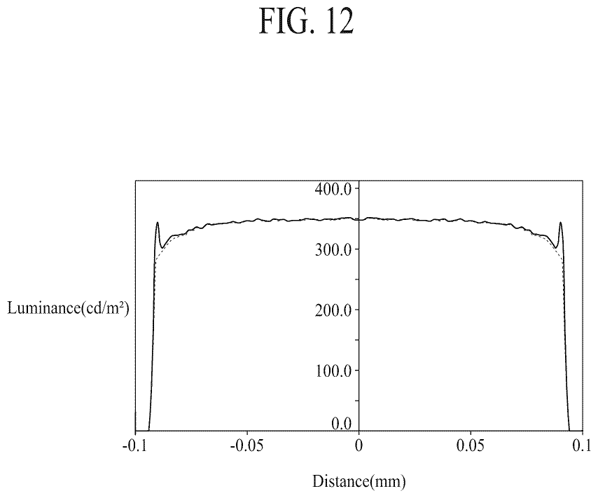

FIG. 12 is a graph showing a luminance of one subpixel according to an experimental example and an embodiment of the invention.

Samples were manufactured corresponding to an embodiment and an experiment example so as to evaluate luminance with respect to positions (for example, a center portion, a left end, and a right end) of one subpixel. An embodiment discloses a sample where a scattering layer is not configured on an inclined surface, and the experimental example is a sample where the scattering layer is configured on the inclined surface. In detail, an embodiment is the light emitting display apparatus described above with reference to FIG. 11 and has a structure where the scattering layer is disposed on a first flat surface (or emission area) of the overcoat layer and is not on the inclined surface (or non-emission area). The experimental example has a structure where the scattering layer is disposed on the first flat surface (or emission area) and the inclined surface of the overcoat layer in the light emitting display apparatus described above with reference to FIG. 11.

In FIG. 12, the X axis represents a horizontal length of one subpixel, and the Y axis represents luminance. The horizontal length (or distance) of the one subpixel is 0.2 mm (200 μm), and 0 is a center portion of the one subpixel, denotes a left end with respect to the center portion toward 0.1 mm from 0, and represents a luminance of a right end with respect to the center portion toward 0.1 mm from 0. In FIG. 12, a solid line represents an embodiment, and a dotted line represents the experiment example. In the experimental example and the embodiment, the inclined surface is disposed at each of the left end and the right end, and in the embodiment, the scattering layer is not disposed on the inclined surface.

Referring to FIG. 12, in the experimental example, it may be seen that luminance is reduced in a ±0.08 mm region compared to the center portion. However, in an embodiment, it may be confirmed that luminance is enhanced in a ±0.09 mm region compared to the center portion, and thus, entire luminance is enhanced. Accordingly, it may be confirmed that luminance is enhanced when the scattering layer is not configured on the inclined surface.

Accordingly, in a structure where the inclined surface is formed in the overcoat layer, it has been confirmed that the scattering layer is not disposed on the inclined surface, and the scattering layer is selectively disposed in only an emission area or on a first flat surface, and thus, light extraction efficiency and luminance based on the inclined surface are enhanced, and moreover, a luminance viewing angle characteristic and the amount of light extraction based on the scattering layer may be enhanced).

The light emitting display apparatus according to embodiments of the invention described above may be applied to mobile devices, video phones, smartwatches, watchphones, wearable devices, foldable devices, rollable devices, bendable devices, flexible devices, curved devices, electronic notebooks, electronic books, portable multimedia players (PMPs), personal digital assistants (PDAs), MP3 players, mobile medical devices, desktop personal computers (PCs), laptop PCs, netbook computers, workstations, navigation systems, automotive navigation systems, automotive display devices, televisions, wallpaper display devices, signage devices, game devices, notebooks, monitors, cameras, camcorders, and home appliances, and the like.

According to one or more embodiments of the invention, a light emitting display apparatus having an enhanced luminance viewing angle characteristic may be provided.

According to one or more embodiments of the invention, a light emitting display apparatus where a luminance viewing angle characteristic and the light extraction efficiency may be increased may be provided.

According to one or more embodiments of the invention, a light emitting display apparatus where power consumption may be reduced through low power driving based on an increase in the light extraction efficiency may be provided. Accordingly, the light emitting display apparatus according to one or more embodiments of the invention may implement environment social governance (ESG), based on an effect of reducing power consumption.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting display apparatus, comprising:
a substrate including a plurality of subpixels each including an emission area and a non-emission area;
an overcoat layer on the emission area and the non-emission area;
a light emitting device layer on the overcoat layer and including a first electrode including a surface modification layer, an emission part on the first electrode, and a second electrode on the emission part; and
a scattering layer between the first electrode and the emission part, the scattering layer contacting the surface modification layer,
wherein the emission part comprises:
an emission layer;
a hole functional layer between the scattering layer and the emission layer; and
an electron functional layer between the emission layer and the second electrode, and
the scattering layer comprises an intermolecular stack structure that forms a light scattering surface.

2. The light emitting display apparatus of claim 1, wherein the surface modification layer is disposed in the emission area of each of the plurality of subpixels and contacts the scattering layer in the emission area.

3. The light emitting display apparatus of claim 1, wherein the scattering layer is disposed in the emission area and the non-emission area and is disposed between the surface modification layer and the hole functional layer in the emission area of each of the plurality of subpixels, and
the emission part covers the light scattering surface and has a shape corresponding to a surface shape of the light scattering surface.

4. The light emitting display apparatus of claim 1, wherein the surface modification layer is an upper surface region of the first electrode that has been surface-treated using an oxygen plasma, and
a surface roughness of the light scattering surface is greater than a surface roughness of the surface modification layer.

5. The light emitting display apparatus of claim 1, wherein the surface roughness of the light scattering surface is in a range of 30 nm to 71 nm, and
the surface roughness of the surface modification layer is in a range of 2 nm to 10 nm.

6. The light emitting display apparatus of claim 1, wherein the scattering layer has a thickness of 500 Å to 1500 Å.

7. The light emitting display apparatus of claim 1, wherein a highest occupied molecular orbital (HOMO) energy level of the scattering layer has a value in a range between a work function of the first electrode and a HOMO energy level of the hole functional layer.

8. The light emitting display apparatus of claim 1, wherein, in each of the plurality of subpixels, a first region of the first electrode disposed in the emission area has a first surface shape different from a second surface shape of a second region of the first electrode disposed in the non-emission area.

9. The light emitting display apparatus of claim 8, further comprising a bank insulation layer disposed on the overcoat layer corresponding to the non-emission area of each of the plurality of subpixels, the bank insulation layer defining the emission area of each of the plurality of subpixels and covering the second region of the first electrode,
wherein the second region of the first electrode has a surface roughness which is less than a surface roughness of the first region of the first electrode, or the second region of the first electrode is a planar portion.

10. The light emitting display apparatus of claim 9, wherein, in the non-emission area of each of the plurality of subpixels, the scattering layer is disposed to cover the bank insulation layer and has a surface shape different from a surface shape of the bank insulation layer.

11. A light emitting display apparatus, comprising:
a substrate including a plurality of subpixels each including an emission area and a non-emission area;
a thin film transistor in the non-emission area;
an overcoat layer in the emission area and the non-emission area, the overcoat layer covering the thin film transistor;
a scattering layer on the overcoat layer; and
a light emitting device layer on the scattering layer and including a first electrode connected to the thin film transistor, an emission part on the first electrode, and a second electrode on the emission part,
wherein the scattering layer comprises an intermolecular stack structure that forms a light scattering surface.

12. The light emitting display apparatus of claim 11, wherein the light emitting device layer disposed in the emission area of each of the plurality of subpixels has a shape corresponding to the light scattering surface.

13. The light emitting display apparatus of claim 12, wherein, in each of the plurality of subpixels, a first region of the light emitting device layer disposed in the emission area has a first surface shape different from a second surface shape of a second region of the light emitting device layer disposed in the non-emission area.

14. The light emitting display apparatus of claim 12, further comprising a bank insulation layer disposed on the overcoat layer corresponding to the non-emission area of each of the plurality of subpixels, the bank insulation layer defining the emission area of each of the plurality of subpixels and covering an edge portion of the first electrode,
wherein, in each of the plurality of subpixels, a surface shape of a first region of the light emitting device layer comprises a shape corresponding to a surface shape of the light scattering surface, and a surface shape of a second region of the light emitting device layer comprises a shape corresponding to a surface shape of the bank insulation layer.

15. The light emitting display apparatus of claim 11, wherein a thickness of the scattering layer is less than 10% of a thickness of the overcoat layer.

16. The light emitting display apparatus of claim 11, wherein the scattering layer has a thickness in a range of 500 Å to 3000 Å, and
a surface roughness of the scattering layer is in a range of 30 nm to 71 nm.

17. The light emitting display apparatus of claim 11, wherein the overcoat layer comprises:
a first flat surface in the emission area;
a second flat surface in the non-emission area and disposed below the first flat surface; and
an inclined surface in the non-emission area and connecting the first flat surface to the second flat surface, and
the scattering layer is disposed on the first flat surface and does not overlap the inclined surface.

18. The light emitting display apparatus of claim 17, wherein the light emitting device layer disposed in the emission area of each of the plurality of subpixels has a shape corresponding to the light scattering surface.

19. The light emitting display apparatus of claim 17, wherein the first electrode contacts the light scattering surface of the scattering layer on the scattering layer and does not overlap the inclined surface.

20. A light emitting display apparatus, comprising:
a substrate including a plurality of subpixels each including an emission area and a non-emission area;
an overcoat layer on the emission area and the non-emission area;
a light emitting device layer on the overcoat layer and including a first electrode including a surface modification layer, an emission part on the first electrode, and a second electrode on the emission part; and
a scattering layer between the first electrode and the emission part, the scattering layer contacting the surface modification layer,
wherein the emission part comprises:
an emission layer;
a hole functional layer between the scattering layer and the emission layer; and
an electron functional layer between the emission layer and the second electrode, and
the scattering layer includes a molecular structure comprising an organic material including a plurality of aromatic rings and a double bond structure, and at least two of the plurality of aromatic rings are rotatable relative to each other.

21. The light emitting display apparatus of claim 20, wherein the scattering layer comprises tetraphenylethylene.

22. The light emitting display apparatus of claim 20, wherein the organic material comprising the molecular structure has a diameter in a range of 10 Å to 25 Å, and a molecular weight of 500 or less.

23. The light emitting display apparatus of one of claim 22, wherein the scattering layer comprises at least one of bathocuproine, a triphenylamine derivative, bathophenanthroline, a perylene derivative, and a pentacene derivative.
